(19) United States
(12) Patent Application Publication
(10) Pub. No.: US 2026/0050127 A1
(43) Pub. Date: Feb. 19, 2026

(54) METHOD FOR FORMING STAIRCASE GRATINGS WITH REDUCED TOP AND BOTTOM CRITICAL DIMENSIONS

(71) Applicant: Applied Materials, Inc., Santa Clara, CA (US)

(72) Inventors: Zefang WANG, Santa Clara, CA (US); Lei JIANG, San Ramon, CA (US); Wenhui WANG, San Jose, CA (US); Yongan XU, Santa Clara, CA (US); Ranida WONGPIYA, Santa Clara, CA (US); Elise LAFFOSSE, Santa Clara, CA (US); Ludovic GODET, Sunnyvale, CA (US)

(21) Appl. No.: 19/301,241

(22) Filed: Aug. 15, 2025

Related U.S. Application Data
(60) Provisional application No. 63/684,028, filed on Aug. 16, 2024.

(51) Int. Cl. G02B 6/34; G02B 27/01; G03F 7/00; G03F 7/26

(52) U.S. Cl. CPC G02B 6/34; G02B 27/0172; G03F 7/0007; G03F 7/26

(57) ABSTRACT

A method for forming waveguide structures is provided. More specifically, embodiments described herein provide techniques for forming staircase gratings with reduced top and bottom critical dimensions.

### CROSS-REFERENCE TO RELATED APPLICATIONS

This application claims the benefit of U.S. Provisional Application 63/684,028 filed on Aug. 16, 2024, which is herein incorporated by reference in its entirety.

### BACKGROUND

### Field

Embodiments of the present disclosure generally relate to optical waveguides. More specifically, embodiments described herein provide techniques for forming a waveguide having staircase gratings.

### Description of the Related Art

Virtual reality is generally considered to be a computer-generated simulated environment in which a user has an apparent physical presence. A virtual reality experience can be generated in 3D and viewed with a head-mounted display (HMD), such as glasses or other wearable display devices that have near-eye display panels as lenses to display a virtual reality environment that replaces an actual environment. Augmented reality, however, enables an experience in which a user can still see through the display lenses of the glasses or other HMD device to view the surrounding environment, yet also see images of virtual objects that are generated for display and appear as part of the environment. Augmented reality can include any type of input, such as audio and haptic inputs, as well as virtual images, graphics, and video that enhances or augments the environment that the user experiences. As an emerging technology, there are many challenges and design constraints with augmented reality.

One such challenge is displaying a virtual image overlaid on an ambient environment. Optical devices including waveguide combiners, such as augmented reality waveguide combiners, and flat optical devices, such as metasurfaces, are used to assist in overlaying images. Generated light is propagated through an optical device until the light exits the optical device and is overlaid on the ambient environment. Optical devices may require gratings with staircase stepped structures or structures having blazed angles relative to the surface of the optical device substrate. Blazed angle gratings are desired in AR waveguides for high diffraction efficiency into the targeted order. However, blazed facets are difficult to manufacture using traditional patterning. Staircase stepped structures are close approximations of blazed angle gratings. Current techniques for forming staircase stepped structures however have inherent limitations in the minimum top and bottom critical dimensions (CD) that can be formed for the staircase stepped structures.

Accordingly, there is a need for improved methods of forming staircase grating structures.

### SUMMARY

In one embodiment, a method for forming a waveguide structure is provided. The method includes forming a patterned hardmask to produce a first plurality of hardmask segments on a device layer, forming a first plurality of photoresist segments over the plurality of hardmask segments and portions of the device layer exposed between the first plurality of hardmask segments, and forming at least one step in portions of the device layer not covered by any of the plurality of photoresist segments or the plurality of hardmask segments. The at least one step in the device layer for forming a first staircase grating. The method also includes forming a second plurality of hardmask segments on the first staircase grating, removing the first plurality of hardmask segments to expose additional portions of the device layer, forming a second plurality of photoresist segments over the second plurality of hardmask segments and the additional exposed portions of the device layer, and forming at least one step in the additional exposed portions of the device layer not covered by any of the second plurality of photoresist segments or the second plurality of hardmask segments. The at least one step formed in the additional exposed portions of the device layer for forming a second staircase grating.

In another embodiment, a method for forming a waveguide structure is provided. The method includes forming a patterned hardmask to produce a plurality of hardmask segments on a device layer, depositing a first photoresist layer on the patterned hardmask, exposing the first photoresist layer to produce a first plurality of photoresist segments, and etching the device layer to produce at least one step. The at least one step produced forms a first staircase grating in the device layer. The method also includes trimming the first plurality of photoresist segments horizontally, depositing a second hardmask on the first staircase grating to produce a second plurality of hardmask segments on the first staircase grating, forming a patterned second photoresist on the second hardmask to produce a second plurality of photoresist segments on the first staircase grating, removing the patterned hardmask and the second plurality of photoresist segments, depositing a third photoresist layer on the first staircase grating, exposing the third photoresist layer to produce a third plurality of photoresist segments, and etching the device layer to produce at least one step. The at least one step etched forms a second staircase grating. The method continues with trimming the third plurality of photoresist segments horizontally, and removing the third plurality of photoresist segments and the second plurality of hardmask segments.

In another embodiment, a waveguide structure is provided. The waveguide structure includes a substrate, an input coupling region disposed over the substrate and comprising a plurality of staircase gratings. Each of the plurality of staircase gratings comprise a sidewall having a depth, a top surface having a top critical dimension less than about 100 nm, a linewidth between sidewalls of adjacent staircase gratings of the plurality of staircase gratings, and a stepped surface having a staircase angle and at least one step. The at least one step includes a bottom surface having a bottom critical dimension less than about 100 nm.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a perspective, frontal view of an optical device, according to certain embodiments.

FIG. 1B is a schematic, cross-sectional view of a plurality of device structures, according to certain embodiments.

FIG. 2 is a flow diagram of a method for forming a waveguide structure, according to certain embodiments.

FIGS. 3A-3W are schematic, cross-sectional views of a waveguide structure undergoing the method for forming a waveguide structure of FIG. 2, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein are generally directed to methods of forming waveguide structures with staircase gratings.

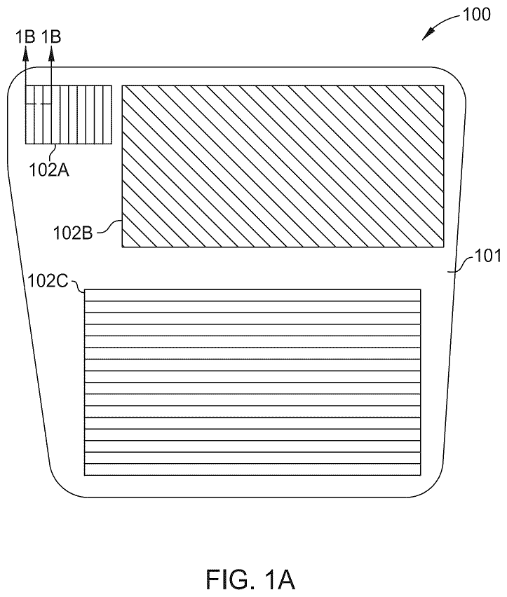

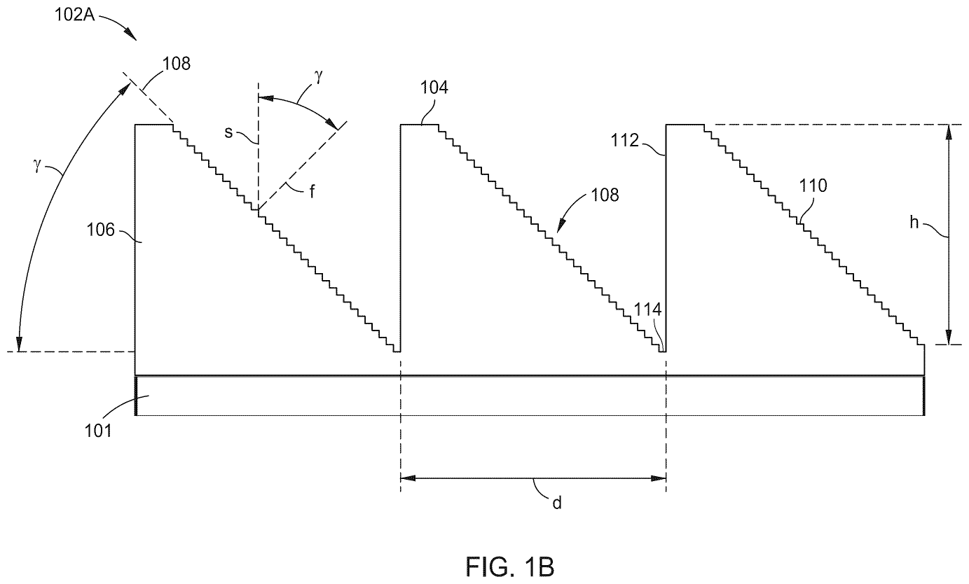

FIG. 1A is a front view of a waveguide combiner 100. It is to be understood that the waveguide combiner 100 described below is an exemplary waveguide combiner. The waveguide combiner 100 includes an input coupling region 102A defined by a plurality of gratings 106 (illustrated in FIG. 1B), a waveguide region 102B, and an output coupling region 102C.

The input coupling region 102A receives incident beams of light (a virtual image) having an intensity from a microdisplay. Each grating of the plurality of gratings 106 splits the incident beams into a plurality of modes. Zero-order mode (TO) beams are refracted back or lost in the waveguide combiner 100. Positive first-order mode (T1) beams undergo total-internal-reflection (TIR) through the waveguide combiner 100 across the waveguide region 102B to the output coupling region 102C and output for display. Negative first-order mode (T-1) beams propagate in the waveguide combiner 100 a direction opposite to the T1 beams. Among the diffracted orders, only the T1 beams output to display through output coupling region 102C, while other modes are lost due to different directionality. Therefore, it is crucial to increase T1 beam intensity and decrease other orders beam intensity for higher device optical efficiency. One approach to increase the intensity of the T1 beams and to reduce the intensity of the other order beams is to control the shape of each grating of the plurality of gratings 106. A staircase shape for each grating of the plurality of gratings 106 provides for increased optical efficiency.

FIG. 1B is a schematic, cross-sectional view of the input coupling region 102A. In one embodiment, which can be combined with other embodiments described herein, the input coupling region 102A includes a plurality of staircase gratings 106 of an optical device. The method 200 described herein forms the plurality of staircase gratings 106 on a substrate 101. The waveguide combiner 100 according to one embodiment, which can be combined with other embodiments described herein, may include the plurality of staircase gratings 106. Each of the staircase gratings 106 includes a top surface 104, a stepped surface 108, a sidewall 112, a bottom surface 114, a depth “h”, and a linewidth “d”. The stepped surface 108 has a plurality of steps 110. In one embodiment, which can be combined with other embodiments described herein, the stepped surface 108 includes at least 3 steps 110, such as greater than 16 steps 110, for example 32 steps 110. The stepped surface 108 has a staircase angle “γ”. The staircase angle γ is the angle between the stepped surface 108 and the surface parallel to the substrate 101 and the angle between the surface normal “s” of the substrate 101 and the facet normal “f” of the stepped surface 108. The depth h corresponds to the height of the sidewall 112 and the linewidth d corresponds to the distances between sidewalls 112 of adjacent staircase gratings 106.

In one embodiment, which can be combined with other embodiments described herein, the staircase angle γ of two or more staircase gratings 106 are different. In another embodiment, which can be combined with other embodiments described herein, the staircase angle γ of two or more staircase gratings 106 are the same. In one embodiment, which can be combined with other embodiments described herein, the depth h of two or more staircase gratings 106 are different. In another embodiment, which can be combined with other embodiments described herein, the depth h of two or more staircase gratings 106 are the same. In one embodiment, which can be combined with other embodiments described herein, the linewidths d of two or more staircase gratings 106 are different. In another embodiment, which can be combined with other embodiments described herein, the linewidths d of one or more staircase gratings 106 are the same.

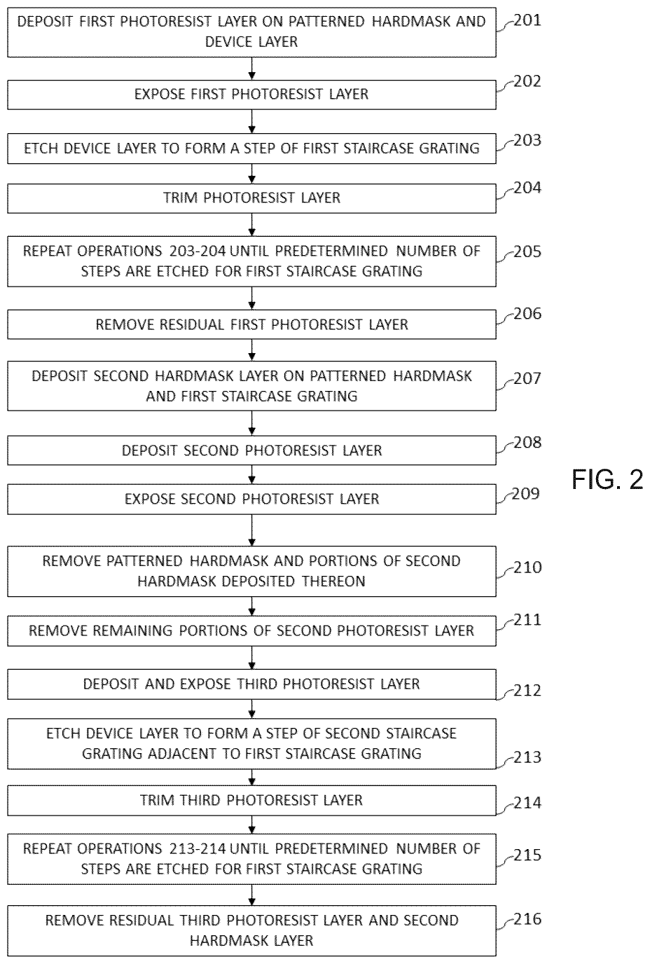

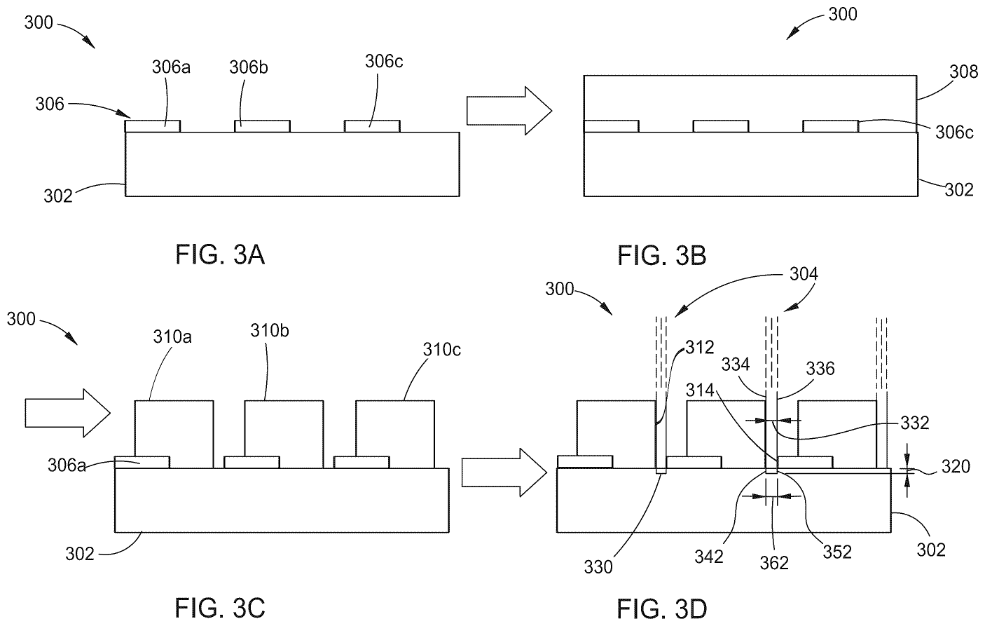

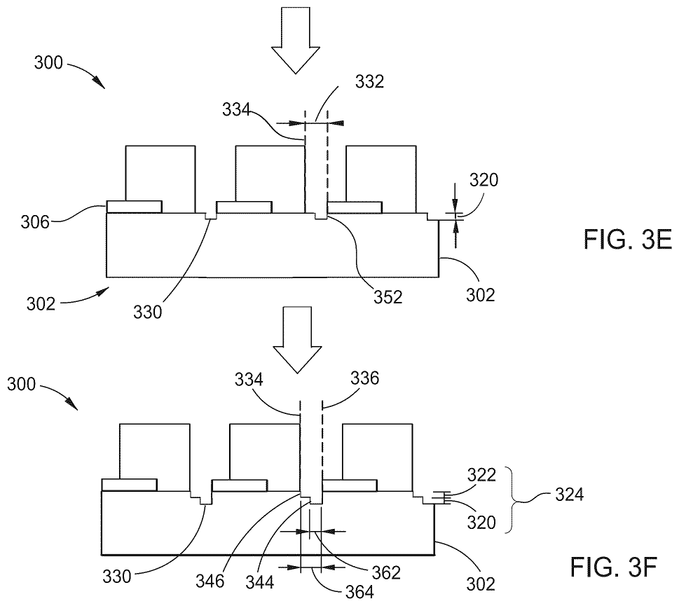

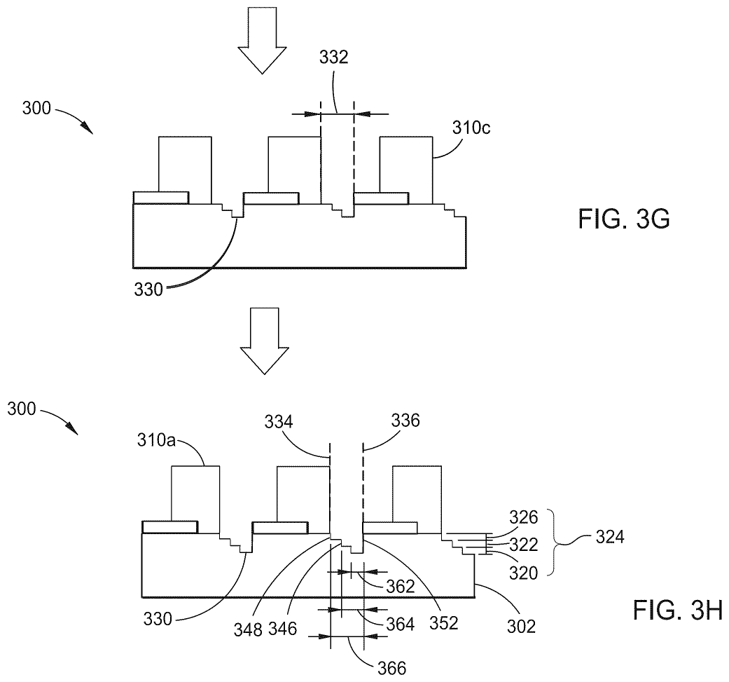

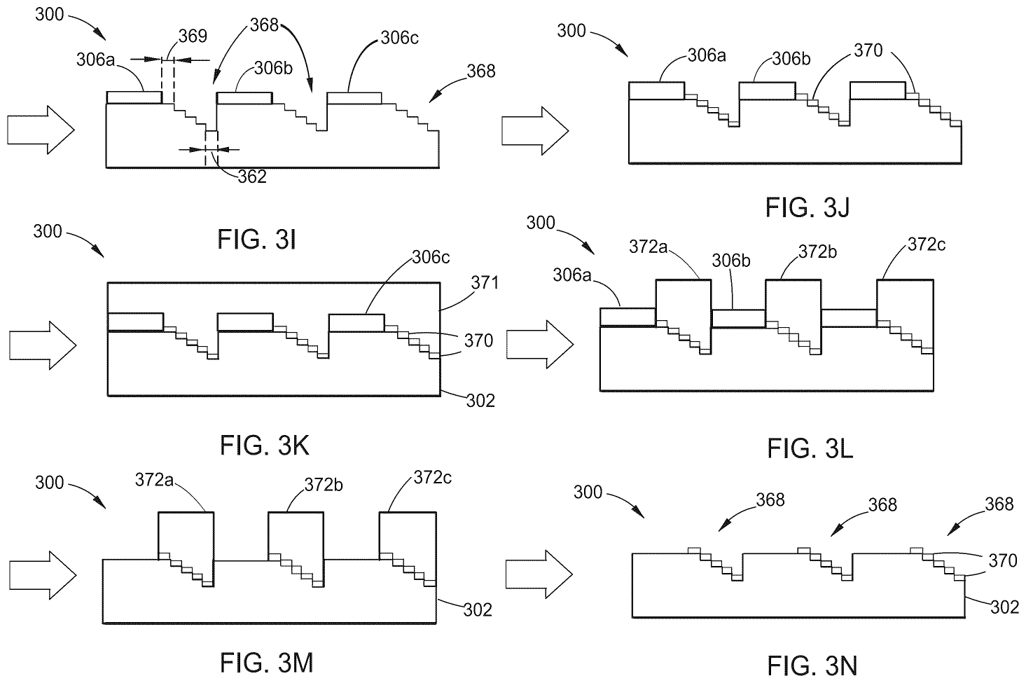

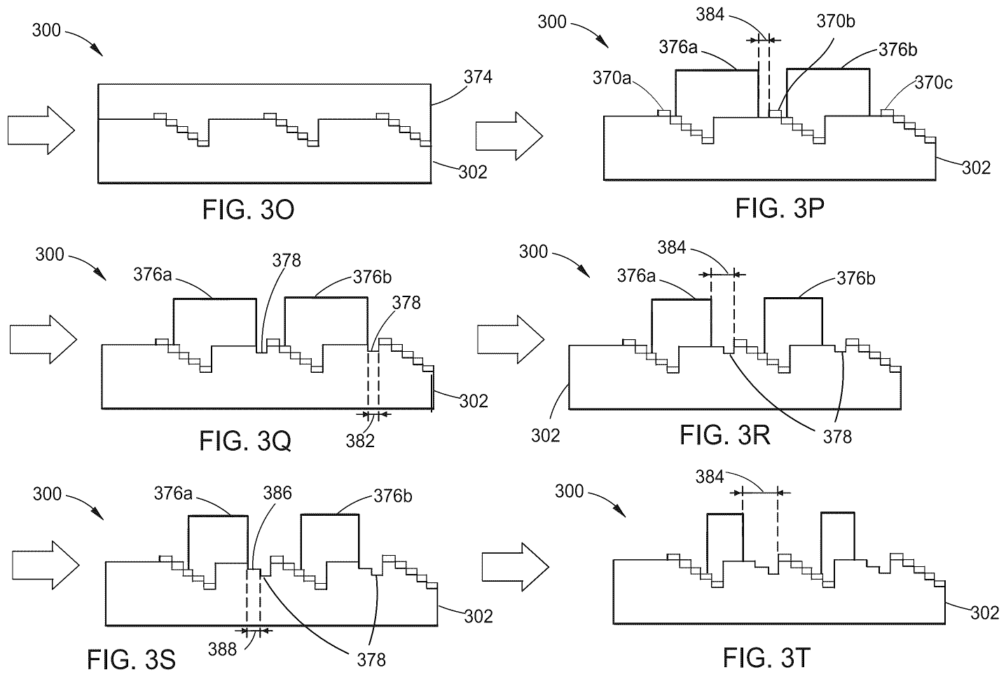

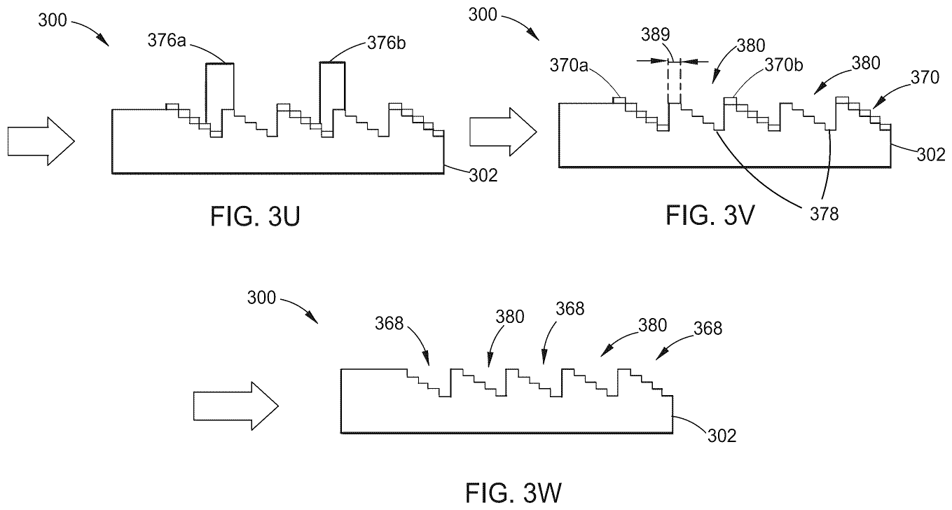

FIG. 2 is a flow diagram of a method 200 for forming a waveguide structure 300 in accordance with one or more embodiments of the present disclosure. FIGS. 3A-3W are views of various stages of forming the waveguide structure 300 in a device layer 302 according to the method 200 of FIG. 2. In one embodiment, the waveguide structure 300 corresponds to the input coupling region 102A of the waveguide combiner 100. In some embodiments, the waveguide structure 300 may be formed from the device layer 302 disposed on the substrate 101. In other embodiments, the device layer 302 and the substrate 101 may be the same layer.

The substrate 101 can be any substrate used in the art and can be either opaque or transparent to a chosen wavelength of light, depending on the use of the substrate 101 as a substrate for a waveguide. Substrate selection may include substrates of any suitable material, including, but not limited to, amorphous dielectrics, non-amorphous dielectrics, crystalline dielectrics, polymers, or combinations thereof. In some embodiments, the substrate 101 includes, but is not limited to, a silicon-containing material, a silicon and oxygen containing compound, a germanium-containing material, a indium and phosphide containing compound, a gallium and arsenic containing compound, a gallium and nitrogen containing compound, a carbon-containing material, a silicon and carbon containing compound, a silicon, carbon, and oxygen containing compound, a silicon and nitrogen containing compound, a silicon, oxygen, and nitrogen containing compound, a niobium and oxygen containing compound, and lithium, niobium, and oxygen containing compound, an aluminum and oxygen containing compound, a indium, tin, and oxygen containing compound, a titanium and oxygen containing compound, a lanthanum and oxygen containing compound, a gadolinium and oxygen containing compound, a zinc and oxygen containing compound, a yttrium and oxygen containing compound, a tungsten and oxygen containing compound, a potassium, and oxygen containing compound, a phosphorous and oxygen containing compound, a barium and oxygen containing compound, a sodium and oxygen containing compound, or combinations thereof. In other embodiments, which can be combined with other embodiments described herein, the substrate 101 includes an oxide including one or more of gadolinium, silicon, sodium, barium, potassium, tungsten, phosphorus, zinc, calcium, titanium, tantalum, niobium, lanthanum, zirconium, lithium, or yttrium containingmaterials. Example materials of the substrate 101 include silicon (Si), silicon monoxide (SiO), silicon dioxide (SiO₂), silicon carbide (SiC), fused silica, diamond, quartz germanium (Ge), silicon germanium (SiGe), indium phosphide (InP), gallium arsenide (GaAs), gallium nitride (GaN), sapphire, sapphire (Al₂O₃), lithium niobate (LiNbO₃), indium tin oxide (ITO), lanthanum oxide (La₂O₃), gadolinium oxide (Gd₂O₅), zinc oxide (ZnO), yttrium oxide (Y₂O₃), tungsten oxide (WO₃), titanium oxide (TiO₂), zirconium oxide (ZrO₃), sodium oxide (Na₂O), niobium oxide (Nb₂O₅), barium oxide (BaO), potassium oxide (K₂O), phosphorus pentoxide (P₂O₅), calcium oxide (CaO), or combinations thereof.

The device layer 302 may include a different material from the substrate 101. The device layer 302 includes, but is not limited to, one or more oxides, carbides, or nitrides of silicon, aluminum, zirconium, tin, tantalum, zirconium, barium, titanium, hafnium, lithium, lanthanum, cadmium, niobium, or combinations thereof. Example materials of the device layer 302 include silicon carbide, silicon oxycarbide, titanium oxide, silicon oxide, vanadium oxide, aluminum oxide, aluminum-doped zinc oxide, indium tin oxide, tin oxide, zinc oxide, tantalum oxide, silicon nitride, zirconium oxide, niobium oxide, cadmium stannate, silicon oxynitride, barium titanate, diamond like carbon, hafnium oxide, lithium niobate, silicon carbon-nitride, silver, cadmium selenide, mercury telluride, zinc selenide, silver-indium-gallium-sulfur, silver-indium-sulfur, indium phosphide, gallium phosphide, lead sulfide, lead selenide, zinc sulfide, molybdenum sulfide, tungsten sulfide, or combinations thereof. In an embodiment, the device layer 302 includes at least one of silicon oxycarbide (SiOC), titanium dioxide (TiO₂), silicon dioxide (SiO₂), vanadium (IV) oxide (VOx), aluminum oxide (Al₂O₃), indium tin oxide (ITO), zinc oxide (ZnO), tantalum pentoxide (Ta₂O₅), silicon nitride (Si₃N₄), titanium nitride (TiN), and zirconium dioxide (ZrO₂) containing materials.

As shown in FIG. 3A, prior to operation 201, a hardmask is disposed and patterned on the device layer 302. The patterned hardmask includes a plurality of hardmask segments, such as a first hardmask segment 306a, a second hardmask segment 306b, and a third hardmask segment 306c that are separated from each other. In certain embodiments, the separation (e.g., distance) between each of the patterned hardmask segments 306a-c will determine the width of each staircase grating structure produced in a first plurality of staircase grating structures. In certain embodiments, the width of each of patterned hardmask segments 306a-c will determine the width of each staircase grating structure produced in a second plurality of staircase grating structures.

FIG. 3B is a schematic cross-sectional view of the device layer. In operation 201, as shown in FIG. 3B, a first photoresist layer 308 is deposited or otherwise placed over the hardmask segments 306. At operation 202 and as shown in FIG. 3C, the first photoresist layer 308 is exposed by lithography to produce a first plurality of photoresist segments, such as a first photoresist segment 310a, a second photoresist segment 310b, and a third photoresist segment 310c. The first plurality of photoresist segments 310a-c directly contacts and cover a portion of the device layer 302 exposed between the hardmask segments 306a-c. In some embodiments, the first plurality of photoresist segments 310a-c partially cover and are offset from each of the plurality of hardmask segments 306a-c such that a portion of each hardmask segment 306a-c is exposed. Further, each of the photoresist segments 310a-c do not extend to the subsequent and adjacent hardmask segment (e.g., from the first hardmask segment 306a to the second hardmask segment 306b). Rather, each of the photoresist segments 310a-c end a distance from each of the subsequent hardmask segment 306a-c.

At operation 203, the device layer 302 is etched by plasma etchant 304 as shown in FIG. 3D. The device layer 302 is exposed to plasma etchant 304, such as radicals and ion beams, contacting the device layer 302. Exposing the device layer 302 to the plasma etchant 304 may include etching processes, such as ion etching and reactive ion etching (RIE). The plasma etchant 304 etches a first depth 320 of a plurality of depths 324 (shown in FIG. 3F) of at least one step 330 formed in the device layer 302. After operation 203, in addition to the first depth 320, the at least one step 330 includes an initial leading sidewall 342 of a leading sidewall 344 (shown in FIG. 3F), a trailing sidewall 352, and a first linewidth 362 from the initial leading sidewall 342 to the trailing sidewall 352. The first linewidth 362 is controlled by a distance 332 between a leading edge plane 334 defined by a first side 312 of each of the first plurality of photoresist segments 310a-c, and a trailing edge plane 336 defined by an exposed side 314 of each of the plurality of hardmask segments 306a-c contacting the device layer 302. The distance 332 corresponds to the first linewidth 362 as the plasma etchant 304 is masked from contacting the device layer 302 outside of the distance 332 by the plurality of hardmask segments 306a-c and each of the first plurality of photoresist segments 310a-c.

At operation 204, photoresist segments 310a, 310b, and 310c are trimmed by an isotropic etching process that recesses the photoresist segments vertically and horizontally. The etch process includes an etch chemistry that etches the photoresist segments from all directions (i.e. the top and side surfaces). In one embodiment, which may be combined with other embodiments described herein, operation 204 includes performing a wet etching process or an isotropic dry etching process. This operation increases the distance 332 between the leading edge plane 334 and the trailing edge plane 336. As shown in FIG. 3E, the distance 332 is increased from the first linewidth 362 (defined by initial leading sidewall 342 to the trailing sidewall 352 shown in FIG. 3D) by the distance between the leading sidewall 344 to the trailing edge plane 334 shown in FIG. 3F.

At optional operation 205, operations 203 and 204 may be repeated to etch at least one second depth 322 of a plurality of depths 324 of the at least one step 330 into the device layer 302. As shown in FIG. 3E, the first plurality of photoresist segments 310a-c are each trimmed to decrease the width of each of the first plurality of photoresist segments 310a-c such that the first side 312 of each of the first plurality of photoresist segments 310a-c is shifted along the device layer 302, increasing the distance 332.

As shown in FIG. 3F, in addition to the second depth 322, the step 330 includes a second leading sidewall

346 and a second linewidth 364 from the second leading sidewall 346 to the trailing sidewall 352. The second linewidth 364 is controlled by the increased distance 332 between the leading edge plane 334 and the trailing edge plane 336 increased by the optional operations 203 and 204. As the distance 332 increases with each iteration of operation 204, the resulting second linewidth 364 is longer than the first linewidth 362 with each subsequent iteration of operation 203. The distance 332 corresponds to the second linewidth 364 as the plasma etchant 304 does not contact the device layer 302 outside of the distance 332. Operation 203 and operation 204 are repeated until the waveguide structure 300 is formed when the at least one step 330 has the plurality of depths 324 including the first depth 320 and the at least one second depth 322 corresponding to a step depth. Decreasing the first depth 320 and each second depth 322 will result in a smoother leading sidewall 344 of the at least one step 330.

As shown in FIG. 3E, in various embodiments, the increase in the distance 332 between each of the first plurality of photoresist segments 310a-c after trimming is uniform and equal to double the first linewidth 362, e.g., the second linewidth 364 is double the length of the first linewidth 362, such that each of the at least one steps 330 are symmetric. In some embodiments, the trimming of each of the photoresist segments 310a-c occurs at both ends of each of the respective photoresist segments 310a-c such that the side of each of the photoresist segments opposite of the first side 312 is shifted along the respective hardmask segments 306a-c. Alternatively, the second linewidth 364 may increase non-uniformly over, e.g., be non-uniformly greater than, the first linewidth 362. For example, the second linewidth 364 may increase by 1.5 times the first linewidth 362, producing a non-symmetric staircase or staircase grating. Similarly, subsequent linewidths may increase symmetrically or non-symmetrically.

As shown in FIGS. 3G and 3H, optional operation 205 includes repeating optional operation 204 after each second depth 322 of the at least one step 330 is etched. For example, at optional operation 204, the photoresist segments 310 are trimmed, further increasing the distance 332. At optional operation 203, a third depth 326 of the plurality of depths 324 is created along with a third leading sidewall 348 and a third linewidth 366 from the third leading sidewall 348 to the trailing sidewall 352. The third linewidth 366 is controlled by distance between the leading edge plane 334 and the trailing edge plane 336, increased by the subsequent optional operation 204. The distance 332 corresponds to the third linewidth 366 as the plasma etchant 304 does not contact the device layer 302 outside of the distance 332.

FIG. 31 is a schematic, cross-sectional view of the waveguide structure 300 after operation 206 of the method 200. In one embodiment, remaining residual portions of the at least one first photoresist layer 308 (e.g., remaining non-trimmed portions of the photoresist segments 310), if present, are removed at operation 206 after a first plurality of staircase grating structures 368 of the waveguide structure 300 is formed between each of the hardmask segments 306a-c. As shown in FIG. 31, each of the first plurality of staircase grating structures 368 formed includes at least one step 330 in which a bottom critical dimension (CD) corresponds with the linewidth 362 and a top critical dimension of each of the first plurality of staircase grating structure 368 corresponding with a linewidth 369.

After operation 206, the at least one step 330 remains and forms the structure of the staircase gratings 106 for each of the first plurality of staircase grating structures 368. Although only five steps are shown in FIG. 31, optional operation 204 may be repeated to produce a desired number of steps, such as 3, such as 10, such as 25, or more. As the number of steps increases, it is noted that the linewidth of each step (e.g., 362, 364) may decrease, producing a smoother leading sidewall (e.g., 342, 344) for each staircase grating 106. For example, the method 200 may enable the formation of a plurality of staircase gratings 106 that each approximate a continuous blazed profile.

At operation 207, a second hardmask is deposited or otherwise disposed over the plurality of hardmask segments 306a-c and each of the at least one step 330 of each of the first plurality of staircase grating structures 368. As shown in FIG. 3J, a corresponding second plurality of hardmask segments 370 is formed over each of the at least one step 330 in the first plurality of staircase grating structures 368 when the second hardmask is deposited. In an embodiment, the material of the second hardmask may be the same as the material of the first patterned hardmask such that the second hardmask formed over each of the plurality of hardmask segments 306a-c causes a thickness of each of each of the hardmask segments 306a-c to increase in operation 207.

At operation 208, as shown in FIG. 3K, a second photoresist layer 371 is deposited or otherwise placed over the patterned hardmask segments 306a-c and each of the second hardmask segments 370. At operation 209 and as shown in FIG. 3L, the second photoresist layer 371 is exposed by lithography to produce a second plurality of photoresist segments, such as a first photoresist segment 372a, a second photoresist segment 372b, and a third photoresist segment 372c. The second plurality of photoresist segments 372a-c directly contact and cover the second plurality of hardmask segments 370 over each of the at least one step 330 of each of the first plurality of staircase grating structures 368 exposed between the hardmask segments 306a-c.

At operation 210, hardmask segments 306a-c are removed exposing a portion of the device layer 302 between the second plurality of photoresist segments 372a-c, as shown in FIG. 3M. In an embodiment in which the material of the hardmask segments 306a-c and the second plurality of hardmask segments 370 are made of the same material, the second plurality of photoresist segments 372a-c prevents the second plurality of hardmask segments 370 on each of the at least one step 330 from being removed in operation 210. At operation 211, the second plurality of photoresist segments 372a-c are removed from each of the plurality of first staircase grating structures 368. As shown in FIG. 3N, after operation 211, portions of the device layer 302 previously covered by the patterned hardmask segments 306a-c are exposed between each of the first plurality of staircase grating structures 368 and corresponding second hardmask segments 370 disposed thereon.

At operation 212, operations similar to operations 201 and 202 are performed to form a plurality of third photoresist segments over the device layer 302. Operation 212 includes depositing a third photoresist layer 374 over the device layer 302 and the second plurality of hardmask segments 370 and exposing the third photoresist layer 374 to form to produce a third plurality of photoresist segments, such as a first photoresist segment 376a and a second photoresist segment 376b. The third plurality of photoresist segments 376a-c directly contact and cover a portion of the device layer 302 exposed between each of the first plurality of staircase grating structures 368.

In some embodiments, as shown in FIG. 3P, the third plurality of photoresist segments 376a-c partially cover and are offset from the second hardmask segments 370 on each of the first plurality of staircase grating structures 368 such that a portion of the second hardmask segments 370 on each of the first plurality of staircase grating structures 368 are exposed. Further, each of the photoresist segments 376a-c do not extend to the subsequent and adjacent second hardmask segment 370 on the top surface of the subsequent adjacent staircase grating structure 368 (e.g., from a second hardmask segment 370a on the top surface of one of the first plurality of staircase grating structure 368 to a second hardmask segment 370b on the top surface of the next staircase grating structure 368 as shown in FIG. 3P). Rather, each of the photoresist segments 376a-c end a distance from each of the subsequent top second hardmask segments 370a-c.

At operation 213, plasma etchant contacts the device layer 302 similar to that as shown in and discussed for FIG. 3D with regards to the plasma etchant 304 used in operation 203. As shown in FIG. 3Q, at least one step 378 for a second plurality of staircase grating structures 380 (shown in FIGS. 3V and 3W) is formed by the plasma etchant in the device layer 302. After operation 213, the at least one step 378 of each of the second plurality of staircase grating structures 380 includes a linewidth 382 controlled by a distance 384 between a leading edge plane defined by a first side of the photoresist segments 376a disposed directly over the device layer 302, and a trailing edge plane defined by an exposed side of a second hardmask segment 370a disposed on the top surface of an adjacent staircase grating structure 368. The distance 384 controls the linewidth 382 etched by the plasma etchant in operation 213 for forming each of the at least one step 378 as the plasma etchant is masked from contacting the device layer 302 outside of the distance 384 by the second hardmask segments 370 and the third plurality of photoresist segments 376.

At operation 214, photoresist segments 376a and 376b of the third photoresist layer 374 are trimmed by an isotropic ion etching process similar to operation 204 discussed above. Operation 214 recesses the photoresist segments vertically and horizontally from both sides of the photoresist segments 376. As shown in FIG. 3R, operation 214 increases the distance 384.

At optional operation 215, operations 213 and 214 may be repeated to etch one or more additional steps of the at least one step 378 into the device layer 302. Operations 213 and 214 for forming the second plurality of staircase grating structures 380 may be repeated similarly to operations 203 and 204 described above for optional operation 205 when forming the at least one step 330 for the first plurality of staircase grating structures 368. As shown in FIG. 3S-3U, after the third plurality of photoresist segments 376a-c are trimmed such that the distance 384 increases, operation 213 may be repeated to etch exposed portions of the device layer 302 and form a second step 386 adjacent to the at least one step 378. A linewidth 388 of the second step 386 is controlled by the change in distance 384 due to the trimming of the third plurality of photoresist segments 376a-c in prior operation 214. As the second step 386 is etched in operation 213, the at least one step 378 previously etched is similarly further etched such that a depth of the at least one step 378 is increased by an etched depth of the second step 386.

FIGS. 3T and 3U show a schematic, cross-sectional view of the waveguide structure 300 after additional iterations of operations 213 and 214 is performed to form additional steps of the at least one step 378 in the device layer 302. As the distance 384 increases with each iteration of operation 214, the resulting linewidth 382 increases with each subsequent iteration of operation 213. Similarly, as additional steps are etched with each subsequent iteration of operation 213, the depth of each of the at least one step 378 previously etched is increased by a depth corresponding to the most recently formed at least one step 378. Decreasing the depth of each subsequently formed step in the device layer 302 may in turn result in a smoother leading sidewall of the at least one step 378. In an embodiment, each of the second plurality of staircase grating structures 380 may be formed the same as each of the first plurality of staircase grating structures 368. In other embodiments, the second plurality of staircase grating structures 380 may be formed different from the first plurality of staircase grating structures 368.

After the waveguide structure 300 is formed in operation 215, the second hardmask segments 370 and the remaining portions of the third plurality of photoresist segments 376a-c may be removed at operation 216. In one embodiment, which can be combined with other embodiments described herein, the second hardmask segments 370 and the remaining portions of the third plurality of photoresist segments 376a-c include non-transparent materials that are removed at operation 216 to form the waveguide structure 300 shown in FIG. 3W. Removing the second hardmask segments 370 may include ion etching, RIE, or selective wet chemical etching. Removing the remaining portions of the third plurality of photoresist segments 376a-c may include a lithography process or etching process described herein.

In another embodiment, which can be combined with other embodiments described herein, the second hardmask segments 370 may include transparent materials such that the second hardmask segments 370 is left on after the waveguide structure 300 is formed in operation 215. FIG. 3V is a schematic, cross-sectional view of the waveguide structure 300 after operation 216 is only partially performed to remove the remaining portions of the third plurality of photoresist segments 376a-c. The second hardmask segments 370 may include, but is not limited to, chromium (Cr), silver (Ag). Si₃N₄. SiO₂, TIN, and carbon (C) containing materials. In a further embodiment, both the third plurality of photoresist segments 376a-c and the second hardmask segments 370 may include transparent materials such that both the second hardmask segments 370 and the remaining portions of the third plurality of photoresist segments 376a-c remain on the waveguide structure 300 after operation 215, as shown in FIG. 3U.

After operation 216, the at least one step 378 between each of the first plurality of staircase grating structures 368 forms the second plurality of staircase grating structures 380 in the device layer 302, as shown in FIG. 3W. Each of the second plurality of staircase grating structures 380 includes at least one step 378 in which a bottom critical dimension (CD) of each of the second plurality of staircase grating structures 380 corresponds with the linewidth 382 of a bottom surface of each of the second plurality of staircase grating structures 380, and a top critical dimension of corresponding with a linewidth 389 of a top surface of the staircase grating structure 380, as shown in FIGS. 3Q and 3V. Although only five steps are shown in FIG. 3W, optional operation 215 may be repeated to produce a desired number of steps, such as 3, such as 10, such as 25, or more. As the number of steps increases, it is noted that the linewidth of each step (e.g., 362, 364) may decrease, producing a smoother leading sidewall (e.g., 342, 344) for each staircase grating structure. For example, the method 200 may enable the formation of a plurality of staircase gratings 106 that each approximate a continuous blazed profile.

Advantages of the present disclosure provide for forming staircase grating structures having reduced top critical dimension (CD_{Top}) and reduced bottom critical dimension (CD_{Bottom}), as compared to staircase grating structures formed utilizing conventional means. In staircase grating structures for waveguides, large CD_{Top} and CD_{Bottom} are generally undesired as they may negatively impact optical performance. In staircase grating structures formed using conventional techniques, the minimum CD_{Bottom} of staircase grating structures are generally limited to 100 nm, which is the minimum gap CD achievable by dry lithography when etching the photoresist segments. Under such limitations, it observed that the bottom and top CDs are in turn limited to the following restriction function (I) below based on the pitch P (i.e. period) of the staircase grating structure to be formed.

$${CD}_{Bottom} + {CD}_{Top} \geq \frac{( P + 100 )}{2} \qquad ( I )$$

The above function provides that in an example of a conventionally formed staircase grating structure in which P is about 400 nm and the minimum gap CD achievable by lithography is about 100 nm, the CD_{Bottom} is about 100 nm for such staircase gratings as mentioned above, and the CD_{Top} in turn must be ≥150 nm.

Conversely, it was observed that for staircase grating structures formed using the techniques of the present disclosure, the bottom and top CDs are limited to the more relaxed restriction function (ii) below:

$$2 \times {CD}_{Bottom} + {CD}_{Top} \geq 100 nm \qquad ( II )$$

Based on the above, for an exemplary staircase grating structure formed using the techniques of the present disclosure and in which the minimum gap CD achievable by lithography is about 100 nm and CD_{Bottom}=CD_{Top}, the present disclosures provides for staircase grating structures in which CD_{Top}≥33 nm and CD_{Bottom}≥33 nm. Accordingly, the present disclosure provides for forming staircase grating structures with much smaller bottom and top CDs.

When introducing elements of the present disclosure or exemplary aspects or embodiments thereof, the articles “a,” “an,” “the” and “said” are intended to mean that there are one or more of the elements.

The terms “comprising,” “including,” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another-even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A method of forming a waveguide structure, comprising:
forming a patterned hardmask to produce a first plurality of hardmask segments on a device layer;
forming a first plurality of photoresist segments over the plurality of hardmask segments and portions of the device layer exposed between the first plurality of hardmask segments;
forming at least one step in portions of the device layer not covered by any of the plurality of photoresist segments or the plurality of hardmask segments, the at least one step forming a first staircase grating;
forming a second plurality of hardmask segments on the first staircase grating;
removing the first plurality of hardmask segments to expose additional portions of the device layer;
forming a second plurality of photoresist segments over the second plurality of hardmask segments and the additional exposed portions of the device layer; and
forming at least one step in the additional exposed portions of the device layer not covered by any of the second plurality of photoresist segments or the second plurality of hardmask segments, the at least one step forming a second staircase grating.

2. The method of claim 1, further comprising removing the second plurality of photoresist segments and the second plurality of hardmask segments after the second staircase grating is formed.

3. The method of claim 1, wherein forming the at least one step for the first staircase grating comprises:
etching the device layer to produce a first step;
trimming the first plurality of photoresist segments horizontally to increase portions of the device layer not covered by any of the plurality of photoresist segments and the plurality of hardmask segments; and
repeating etching the device layer and trimming the first plurality of photoresist segments horizontally to produce a second step of the first staircase grating.

4. The method of claim 1, wherein forming the at least one step for the second staircase grating comprises:
etching the additional exposed portions of the device layer device layer to produce a first step;
trimming the second plurality of photoresist segments horizontally to increase the additional exposed portions of the device layer; and
repeating etching the additional exposed portions of the device layer and trimming the second plurality of photoresist segments horizontally to produce a second step of the second staircase grating.

5. The method of claim 1, further comprising removing the first plurality of photoresist segments prior to forming the second plurality of hardmask segments.

6. The method of claim 1, further comprising wherein removing the first plurality of hardmask segments comprises:
forming a photoresist layer on the patterned hardmask and the second plurality of hardmask segments on the first staircase grating;
exposing the photoresist layer to produce a third plurality of photoresist segments over the second plurality of hardmask segments on the first staircase grating; and
etching the first plurality of hardmask segments exposed between the third plurality of photoresist segments.

7. A method of forming a waveguide structure, comprising:
forming a patterned hardmask to produce a plurality of hardmask segments on a device layer;
depositing a first photoresist layer on the patterned hardmask;
exposing the first photoresist layer to produce a first plurality of photoresist segments;
etching the device layer to produce at least one step, the at least one step forming a first staircase grating;
trimming the first plurality of photoresist segments horizontally;
depositing a second hardmask on the first staircase grating to produce a second plurality of hardmask segments on the first staircase grating;
forming a patterned second photoresist on the second hardmask to produce a second plurality of photoresist segments on the first staircase grating;
removing the patterned hardmask and the second plurality of photoresist segments;
depositing a third photoresist layer on the first staircase grating;
exposing the third photoresist layer to produce a third plurality of photoresist segments;
etching the device layer to produce at least one step, the at least one step forming a second staircase grating;
trimming the third plurality of photoresist segments horizontally; and
removing the third plurality of photoresist segments and the second plurality of hardmask segments.

8. The method of claim 7, further comprising:
before depositing the second hardmask, repeating etching the device layer and trimming the first plurality of photoresist segments horizontally to produce a second step of the first staircase grating.

9. The method of claim 7, further comprising:
before removing the third plurality of photoresist segments and the remaining portion of the second hardmask, repeating etching the device layer and trimming the third plurality of photoresist segments horizontally to produce a second step of the second staircase grating.

10. The method of claim 7, wherein the at least one step of the first grating structure includes a first depth into the device layer.

11. The method of claim 8, wherein the at least one step of the first staircase grating includes a first depth into the device layer and the second step includes a second depth into the device layer, the first depth being greater than the second depth.

12. The method of claim 9, wherein the at least one step of the second staircase grating includes a first depth into the device layer and the second step includes a second depth into the device layer, the first depth being greater than the second depth.

13. The method of claim 7, further comprising removing residual portions of the first plurality of photoresist segments before depositing the second hardmask.

14. The method of claim 7, wherein a linewidth of the first staircase grating is determined by a distance between each of the plurality of hardmask segments.

15. The method of claim 7, wherein a linewidth of the second staircase grating is determined by a width of each of the plurality of hardmask segments.

16. The method of claim 7, wherein the first plurality of photoresist segments are offset from the plurality of hardmask segments of the patterned hardmask such that a portion of each of the first plurality of photoresist segments directly contact a portion of the device layer.

17. The method of claim 7, wherein depositing the second hardmask on the first staircase grating produces a second plurality of hardmask segments on the at least one step of the first staircase grating, and the third plurality of photoresist segments are offset from the second hardmask segments of the second hardmask such that a portion of each of the third plurality of photoresist segments directly contact a portion of the device layer.

18. The method of claim 7, wherein the at least one step of the first staircase grating includes a first linewidth controlled by a distance between a leading edge plane defined by a first side of a photoresist segment of the first plurality of photoresist segments and a trailing edge plane defined by an exposed side of a hardmask segment of the plurality of hardmask segments.

19. The method of claim 7, wherein the at least one step of the second staircase grating includes a first linewidth controlled by a distance between a leading edge plane defined by a first side of a photoresist segment of the third plurality of photoresist segments and a trailing edge plane defined by an exposed side of a second hardmask segment disposed over a top surface of the first staircase grating.

20. A waveguide structure, comprising:
a substrate;
an input coupling region disposed over the substrate and comprising a plurality of staircase gratings, each of the plurality of staircase gratings comprising:
a sidewall having a depth;
a top surface having a top critical dimension less than about 100 nm;
a linewidth between sidewalls of adjacent staircase gratings of the plurality of staircase gratings; and
a stepped surface having a staircase angle and at least one step, the at least one step comprising a bottom surface having a bottom critical dimension less than about 100 nm.
